(19) United States
(12) Patent Application Publication
(10) Pub. No.: US 2025/0015764 A1
(43) Pub. Date: Jan. 9, 2025

(54) MULTIBAND DOHERTY POWER AMPLIFIER

(71) Applicant: COMMISSARIAT A L’ENERGIE ATOMIQUE ET AUX ENERGIES ALTERNATIVES, PARIS (FR)

(72) Inventors: Ayssar SERHAN, GRENOBLE (FR); Pascal REYNIER, GRENOBLE (FR); Alexandre GIRY, GRENOBLE (FR)

(21) Appl. No.: 18/765,224

(22) Filed: Jul. 6, 2024

(30) Foreign Application Priority Data
Jul. 7, 2023 (FR) 2307281

(51) Int. Cl. H03F 1/02; H03F 1/56; H03F 3/21

(52) U.S. Cl. CPC H03F 1/0288; H03F 1/56; H03F 3/211; H03F 2200/141; H03F 2200/213; H03F 2200/222; H03F 2200/423; H03F 2200/451; H03F 2200/61

(57) ABSTRACT

A Doherty amplifier includes: an input port; a pre-amplification stage; and at least one output port. The Doherty amplifier further includes: a high-band amplification pathway; a low-band amplification pathway; the high-band amplification pathway (VA_{HB}) and the low-band amplification pathway each having a main amplifier, an auxiliary amplifier, and an output impedance matching network. A common network is connected to the high-band amplification pathway and to the low-band amplification pathway, the common network having a switch configured to selectively activate the high-band amplification pathway or the low-band amplification pathway. An intermediate impedance matching network is distributed between the common network, the high-band amplification pathway and the low-band amplification pathway.

### CROSS-REFERENCE TO RELATED APPLICATION

This application claims priority to foreign French patent application No. FR 2307281, filed on Jul. 7, 2023, the disclosure of which is incorporated by reference in its entirety.

### FIELD OF THE INVENTION

The present invention relates to a multiband Doherty power amplifier. The invention is applicable, in particular, to telecommunications devices which may be used in mobile telephone networks or in Wi-Fi networks.

4G/5G/6G and Wi-Fi 6/6E/7 modern communication standards considerably increase the complexity of RF front-end modules, of which the power amplifier is a critical part, in terms of size and of energy consumption.

Specifically, the need for reduced energy consumption with reduced size and manufacturing cost is pushing research towards multiband power amplifiers with high efficiency and a high level of integration, with strong linearity requirements.

Signals used in 4G/5G/6G and Wi-Fi 6/6E/7 standards have high peak-to-average power ratios (PAPRs) (greater than 4 dB) because, notably, of the presence of a large number of modulated subcarriers in these OFDM communication systems.

With a high PAPR, it is all the more necessary to lower the power level of the power amplifier with respect to the peak power (back-off), in order to meet strict linearity specifications.

More specifically, the power back-off is a power level below the saturation point which makes it possible to make the amplifier operate in a linear zone. Usually, power amplifiers operate close to the saturation point since it is there that the efficiency is maximum. In order to ensure that the amplifier is operating in the linear zone, the power level is lowered from the point of maximum efficiency. The power reduction level is called “power back-off”.

In power amplifiers of the prior art, power reduction considerably degrades the average efficiency of the power amplifier. Thus, besides the fact that the power amplifier must preserve high efficiency despite the power back-off, the power amplifier must also be wideband or multiband in order to cover an increased number of frequency bands.

The Doherty power amplifier is an advantageous solution for efficiently amplifying signals with high PAPRs. The operating principle of the Doherty amplifier is illustrated by FIG. 1, and in more detail in [1]. The input signal RF_{IN} is pre-amplified by a pre-amplification stage 1 and the signal is separated by a power divider 5. The Doherty amplifier comprises a main amplifier 2, an auxiliary amplifier 3, an impedance matching circuit 6 at the input of the main amplifier 2 and of the auxiliary amplifier 3, and an output impedance matching circuit 4 comprising a quarter-wavelength line here playing the role of an impedance inverter. It is possible to consider other types of combiners which do not necessarily use a quarter-wavelength line. The impedance matching circuit 6 applies a predetermined phase equalization between the main chain and the auxiliary chain. An output matching network (not shown) possibly makes it possible to transform the load impedance of the system (conventionally 50 ohms) into an optimal operating impedance.

The Doherty power amplifier uses the concept of active (or dynamic) load modulation, wherein the load seen by the main amplifier 2 is modulated by injecting a current from the auxiliary amplifier 3. The main amplifier 2, conventionally operating in class AB, is always active, while the auxiliary amplifier 3, conventionally operating in class C or deep AB, contributes only in the back-off region.

Doherty power amplifiers generally have a limited optimal operating band (fractional band FBW<10%) and require accurate phase control at the impedance matching circuit 6 in order to maintain high performance (efficiency and linearity) over the targeted frequency band.

The operating fractional band is given by the following relationship:

FBW=(Fmax−Fmin)/Fcentral

with Fmin being the minimum frequency of the operating band, Fmax the maximum frequency of the operating band, and Fcentral the centre frequency.

In order to overcome the degradation of the performance of Doherty power amplifiers over a high frequency range, tunable Doherty power amplifier architectures have recently been introduced.

In [2], a Doherty power amplifier architecture having a widened frequency band (1.55-2.3 GHZ) comprises several tunable capacitors. The amplifier requires the use of an (external) digital pre-distortion technique, in order to maintain the linearity level required over the whole frequency band, which damages the energy efficiency of the system.

In [3], an alternative Doherty power amplifier architecture has linear behaviour over the 1.9 GHZ-2.7 GHz band without requiring a digital pre-distortion technique. The amplifier comprises tunable capacitors integrated on SOI-CMOS, which improves the linearity in frequency. However, the operating band FBW remains less than 25%.

There is therefore a need to provide a linear Doherty power amplifier having an improved fractional operating band FBW, and not using a digital pre-distortion technique.

### SUMMARY

One subject of the invention is therefore a Doherty amplifier as defined according to claims 1 to 5.

### BRIEF DESCRIPTION OF THE DRAWING FIGURES

Other features, details and advantages of the invention will become apparent on reading the description given with reference to the appended drawings, which are given by way of example.

FIG. 1, which has already been described, illustrates the operating principle of a Doherty power amplifier.

FIG. 2a and FIG. 2b illustrate detailed views of a Doherty power amplifier circuit according to the invention, and FIG. 2c illustrates a variant of FIG. 2b.

FIG. 3 illustrates various performance levels obtained with the Doherty power amplifier circuit according to the invention.

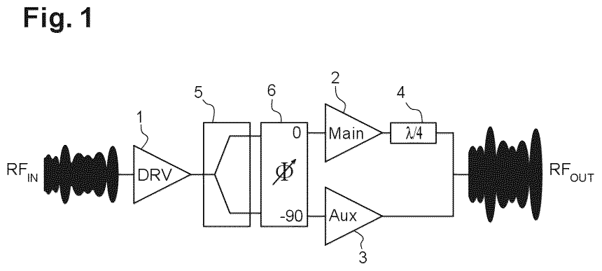

### DETAILED DESCRIPTION

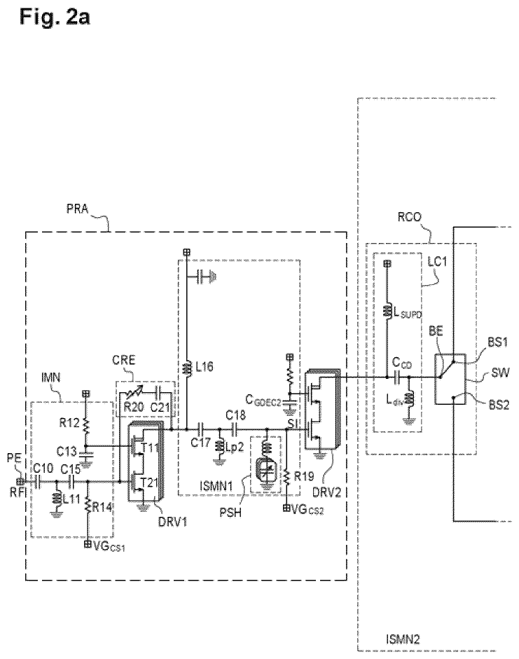

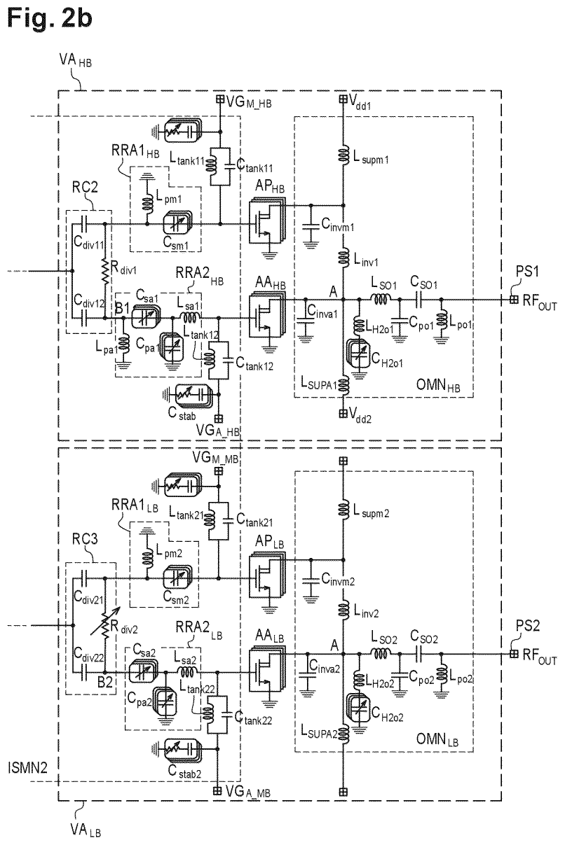

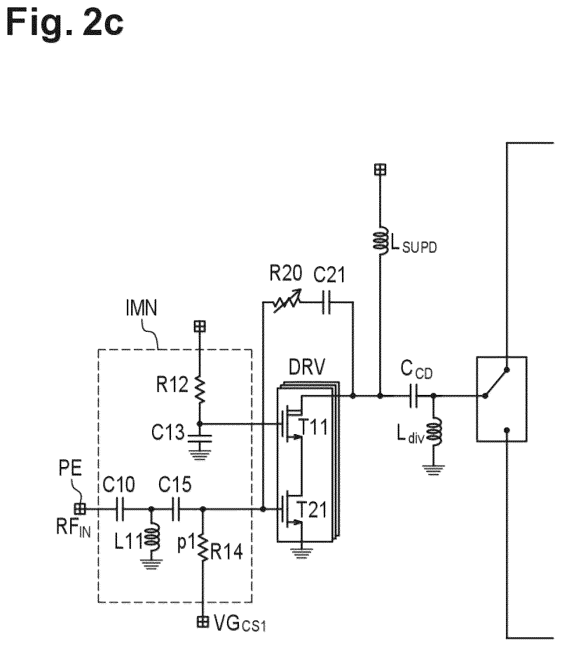

The Doherty amplifier according to the invention is illustrated by FIGS. 2a, 2b and 2c.

The input port PE receives the input RF signal RF_{IN} to be amplified. A pre-amplification stage PRA makes it possible to amplify the input RF signal RF_{IN}, so as to generate an intermediate signal SI, in order to increase the overall gain of the Doherty amplifier.

A common network RCO, which comprises a switch SW, is connected at the output of the pre-amplification stage PRA. The common network RCO is also connected to a high-band amplification pathway VA_{HB} and to a low-band amplification pathway VA_{LB}. The switch SW may selectively activate the high-band amplification pathway VA_{HB} or the low-band amplification pathway VA_{LB} in accordance with the carrier frequency of the input RF signal. The Doherty amplifier also comprises external means for controlling the bias signals for the transistors according to whether the high-band amplification pathway VA_{HB} or the low-band amplification pathway VA_{LB} is selected.

To this end, the switch SW comprises an input terminal BE, connected to the pre-amplification stage PRA, and two output terminals. One output terminal BS1 is connected to the high-band amplification pathway VA_{HB}, and one output terminal BS2 is connected to the low-band amplification pathway VA_{LB}. One example of a switch which may be used is an SPDT (single-pole double-throw) switch with one input and two outputs.

One or other of the amplification pathways of the Doherty amplifier is selected automatically in accordance with the knowledge of the carrier frequency of the signal to be amplified.

For example, the amplification pathways may be switched between dynamically, that is to say when the Doherty amplifier is in use. According to another embodiment, the Doherty amplifier, integrated into a telecommunications device (for example a base station or a user terminal), may control the switching between the amplification pathways in accordance with the movement of the user and/or with the changing of cell by the user.

The switch from one amplification pathway to the other may be controlled by a control device (not shown in the figures).

The high-band amplification pathway VA_{HB} is adapted to amplify the intermediate signal, the operating frequency band of which is located in a frequency band referred to as the upper frequency band. According to the operating principle of the Doherty amplifier recalled above, the high-band amplification pathway VA_{HB} comprises a main amplifier AP_{HB} operating in class AB, and an auxiliary amplifier AA_{HB} operating in the class C or deep AB. Moreover, the high-band amplification pathway VA_{HB} comprises an output impedance matching network OMN_{HB} connected to the main amplifier AP_{HB}, to the auxiliary amplifier AA_{HB} and to the output port PS1 at which the amplified signal is extracted. The signals originating from the main amplifier and auxiliary amplifier are recombined at the node A.

The main/auxiliary amplifier may be composed of a transistor (LDMOS transistor in FIGS. 2a and 2b but another type of transistor may be used), of a stack of transistors (the case for the driver stages, but this might also be the case for the output stage), or of a combination of transistors.

Advantageously, the main amplifier and the auxiliary amplifier of each pathway comprise LDMOS (laterally-diffused metal-oxide-semiconductor) transistors, which offer a high breakdown voltage (greater than 10 volts), which is necessary for applications requiring high output powers (>1 W) such as mobile telephones or telecommunications base stations. Other technologies may be envisaged for the transistors of the power stage, notably MOS+MOS or MOS+LDMOS stacked transistors, BiCMOS or indeed GaAs, GaN or InP transistors.

According to one embodiment, the output of the main amplifier AP_{HB} (drain of the transistor) is connected to the output of the auxiliary amplifier AA_{HB} (drain of the transistor) by means of an impedance inverter such as a pi network with localized elements which is equivalent to a quarter-wavelength line. The impedance inverter is composed of a capacitor Cᵢₙᵥₘ₁ connected between the output of the main amplifier AP_{HB} and ground, of a capacitor Cᵢₙᵥₐ₁ connected between the output of the auxiliary amplifier AA_{HB} and ground, and of a coil Lᵢₙᵥ₁ connecting the two outputs of the main amplifier AP_{HB} and of the auxiliary amplifier AA_{HB}.

The output combiner may adopt a different topology, such as a topology described in [4].

The capacitors Cᵢₙᵥₘ₁ and Cᵢₙᵥₐ₁ and the coil Lᵢₙᵥ₁ are sized so that the characteristic impedance Z_{c} of the impedance inverter is equal to Z_{c}=2×Zₒₚₜ, with Zₒₚₜ being the optimal load impedance at the node A, which corresponds to the output of the auxiliary amplifier AA_{HB}.

The output network OMN_{HB} comprises a coil L_{SUPM1} connected between the external power supply voltage source V_{dd} of the main amplifier AP_{HB} and the output of the main amplifier AP_{HB}. Likewise, a coil L_{SUPA1} is connected between the external power supply voltage source V_{dd2} of the auxiliary amplifier AA_{HB} and the node A.

A controllable resonant network, composed of a coil L_{H2o1} and of a variable capacitor C_{H2o1}, is connected between the node A and ground. This resonant network constitutes a controllable harmonic termination which is used to improve the rejection of the second harmonic with respect to the fundamental frequency.

The LC filter composed of a coil L_{SO1}, of a capacitor C_{SO1}, of the capacitor C_{PO1} and of the coil Lₚₒ₁ is part of the network for matching output to the fundamental frequency.

The low-band amplification pathway VA_{LB} is adapted to amplify the intermediate signal, the operating frequency band of which is located in a frequency band referred to as the lower frequency band. It comprises an output impedance matching network OMN_{LB} of the low-band amplification pathway which may be identical (but not necessarily) to the output impedance matching network OMN_{HB} of the high-band amplification pathway, the sizing of the components being able to be different from one pathway to the other.

The Doherty amplifier comprises an output port PS1 for the high-band amplification pathway VA_{HB} and an output port PS2 for the low-band amplification pathway VA_{LB}. The output port PS1 of the high-band amplification pathway VA_{HB} may be connected to an antenna or to an antenna select switch, and the output port PS2 of the low-band amplification pathway VA_{LB} may be connected to a different antenna or to an antenna select switch.

The upper frequency band and the lower frequency band are preferably disjoint. For example, the components of the high-band amplification pathway VA_{HB} may be sized in order to amplify the input signal in the 2.1-2.7 GHz operating band, while the components of the low-band amplification pathway VA_{LB} may be sized in order to amplify the input signal in the 1.7-2.1 GHz operating band.

The Doherty amplifier according to the invention comprises an intermediate impedance matching network ISMN2, connected between the pre-amplification stage PRA and each of the main amplifiers (AP_{HB}, AP_{LB}) and auxiliary amplifiers (AA_{HB}, AA_{LB}). The intermediate impedance matching network ISMN2 makes it possible to present an optimal source impedance to each of the amplifiers. It is advantageously distributed between the common network RCO, the high-band amplification pathway VA_{HB} and the low-band amplification pathway VA_{LB}. Thus, some of the components of the intermediate impedance matching network ISMN2 are part of the common network RCO, while other components of the intermediate impedance matching network ISMN2 are part of the high-band amplification pathway VA_{HB} and of the low-band amplification pathway VA_{LB}.

The design of the intermediate impedance matching network ISMN2 is a critical aspect in order to obtain good RF performance for the Doherty amplifier. Specifically, it must present both an optimal source impedance for the output stages and an optimal load impedance for the pre-amplification stage.

The fact that some of the components of the intermediate impedance matching network ISMN2 are part of the common network RCO, between the pre-amplification stage PRA and the switch SW, makes it possible to reduce the size of the chip on which the Doherty amplifier is etched.

Thus, the power divider stage, which makes it possible to distribute the power of the signal between the main amplifier AP_{HB} and the auxiliary amplifier AA_{HB}, comprises a first resonant circuit LC1 arranged in the common network RCO, a second resonant circuit RC2 arranged in the high-band amplification pathway VA_{HB}, and a third resonant circuit RC3 arranged in the low-band amplification pathway VA_{LB}.

The first resonant circuit LC1 comprises a capacitor C_{CD} connected between the output of the pre-amplification stage PRA and the input terminal of the switch SW, and an inductor L_{div} connected between the input terminal of the switch SW and ground.

The second resonant circuit RC2 comprises two capacitors (C_{div11}, C_{div12}) connected in parallel across the resistor R_{div1}. The two capacitors are connected to the output terminal of the switch SW which activates the high-band amplification pathway VA_{HB}. The capacitor C_{div11} is on the branch of the main amplifier AP_{HB}, and the capacitor C_{div12} is on the branch of the auxiliary amplifier AA_{HB}. An inductor Lₚₐ₁ is connected between the capacitor C_{div12} and ground. The resistor R_{div1} connects the capacitors (C_{div11}, C_{div12}) connected in parallel. The resistor R_{div1} may be a variable resistor, in order to adjust the amplitude and the phase on the high-band amplification pathway VA_{HB}.

The shared inductor L_{div} thus forms a modified Wilkinson divider with the capacitors C_{div11} and C_{div12} and the resistor R_{div1} when the high-band amplification pathway VA_{HB} is activated and with the capacitors C_{div21} and C_{div22} and the resistor R_{div2} when the low-band amplification pathway VA_{LB} is activated.

The third resonant circuit RC3 comprises two capacitors (C_{div21}, C_{div22}) connected in parallel across the resistor R_{div2}. The two capacitors are connected to the output terminal of the switch SW which activates the low-band amplification pathway VA_{LB}. The resistor R_{div2} connects the capacitors (C_{div21}, C_{div22}) connected in parallel.

According to one embodiment of the invention, in the high-band amplification pathway VA_{HB}, a first tunable resonant network RRA1_{HB} is connected to the gate of the main amplifier AP_{HB} and configured to introduce a predefined first phase shift ϕₘ. To this end, the first tunable resonant network RRA1_{HB} comprises an inductor Lₚₘ₁, connected between the second resonant circuit RC2 and ground, and a variable capacitor Cₛₘ₁ connected between the second resonant circuit RC2 and the gate of the main amplifier AP_{HB}.

Likewise, in the high-band amplification pathway VA_{HB}, a second tunable resonant network RRA2_{HB} is connected to the gate of the auxiliary amplifier AA_{HB} and configured to introduce a predefined second phase shift a. To this end, the second tunable resonant network RRA2_{HB} comprises an inductor Lₚₐ₁, connected between a node B1 and ground. The node B1 connects the second resonant circuit RC2 to the gate of the auxiliary amplifier AA_{HB} via a variable capacitor Cₛₐ₁ placed in series with an inductor Lₛₐ₁. A capacitor Cₚₐ₁ is connected between an intermediate point, situated between the variable capacitor Cₛₐ₁ and the inductor Lₛₐ₁, and ground.

The first tunable resonant network RRA1_{HB} is sized and controlled so that it presents the optimal source impedance to the main amplifier AP_{HB} while at the same time introducing the predefined first phase shift ϕₘ. Likewise, the second tunable resonant network RRA2_{HB} is sized and controlled so that it presents the optimal source impedance to the auxiliary amplifier AA_{HB} while at the same time introducing the predefined second phase shift ϕₐ.

In the low-band amplification pathway VA_{LB}, a first tunable resonant network RRA1_{LB} is identical to the first resonant network RRA1_{HB} of the high-band amplification network VA_{HB}. The first tunable resonant network RRA1_{LB} introduces a predefined first phase shift ϕₘ.

In the low-band amplification pathway VA_{LB}, a second tunable resonant network RRA2_{LB} is connected to the gate of the auxiliary amplifier AA_{LB} and configured to introduce a predefined second phase shift Da to the RF signal. To this end, the second tunable resonant network RRA2_{LB} comprises a variable capacitor Cₛₐ₂ placed in series with an inductor Lₛₐ₂. A capacitor Cₚₐ₂ is connected between an intermediate point, situated between the variable capacitor Cₛₐ₂ and the inductor Lₛₐ₂, and ground.

According to one particularly advantageous embodiment, the second tunable resonant network RRA2_{LB} of the low-band amplification pathway VA_{LB} does not comprise an inductor connected between the node B2 and ground. The second tunable resonant network RRA2_{LB} of the low-band amplification pathway VA_{LB} thus comprises one inductor (or coil) fewer than the second tunable resonant network RRA2_{HB} of the high-band amplification pathway VA_{HB}.

Specifically, the switch SW does not offer perfect isolation between the high-band amplification pathway VA_{HB} and the low-band amplification pathway VA_{LB}. When the low-band amplification pathway VA_{LB} is activated, the intermediate impedance matching network ISMN2 is capable of forming the impedance and phase level required, taking account of the parasites of the inactive path (that is to say of the high-band amplification pathway VA_{HB}). The variable capacitors of the amplification pathways and the bias voltages of the transistors may also be adjusted so that performance is optimized in accordance with the targeted frequency. The resistor R_{div2} of the third resonant circuit RC3 may be a variable resistor, which makes it possible to adjust the amplitude and phase levels required, taking account of the parasites of the inactive path.

Thus, the parasitic impedance of the high-band amplification pathway VA_{HB} makes it possible to do without an additional bulky inductor in the second tunable resonant network RRA2_{LB} of the low-band amplification pathway VA_{LB}.

This is particularly advantageous for a use of the Doherty amplifier in applications which are constrained in size such as mobile telephones, smart objects or small cells.

In the high-band amplification pathway VA_{HB} and in the low-band amplification pathway VA_{LB}, the value of the first phase shift ϕₘ and the value of the second phase shift ϕₐ are determined so that their difference has a predefined value in the back-off region of the main amplifier (AP_{HB}, AP_{LB}) and of the auxiliary amplifier (AA_{HB}, AA_{LB}).

The phase difference ϕ_{diff}=ϕₘ−ϕₐ is optimized in order to ensure optimal load modulation and power combination, at the node A, in the back-off region (ϕ_{diff} is substantially equal to 90° in theory). At a given frequency, the difference ϕ_{diff} depends on the power because of the non-linearity of the input impedances of the main amplifier and of the auxiliary amplifier. These input impedances, as well as the transfer function of the intermediate impedance matching networks, vary in accordance with the frequency. These effects lead to variation of ϕ_{diff} and degrade the performance of the Doherty amplifier. In order to avoid such degradation, ϕ_{diff} is optimized and readjusted in the back-off zone (typical back-off value of 4 to 8 dB for mobile applications).

In each of the amplification pathways, the baseband impedances at the gate and at the drain of the main amplifier and of the auxiliary amplifier introduce a memory effect and cause degradation of the linearity performance. In order to attenuate this effect, the main amplifier and the auxiliary amplifier are biased via a parallel LC resonator (Lₜₐₙₖ₁₁−Cₜₐₙₖ₁₁, Lₜₐₙₖ₁₂−Cₜₐₙₖ₁₂, Lₜₐₙₖ₂₁−Cₜₐₙₖ₂₁, Lₜₐₙₖ₂₂−Cₜₐₙₖ₂₂) connected to the gate of the transistors.

According to one embodiment, the pre-amplification stage PRA (or driver) comprises two stages connected in a cascade, with a first amplifier stage DRV1 and a second amplifier stage DRV2 (which is connected to an external power supply source via an inductor L_{supd}), in order to maintain a high power gain (typically of the order of 30 dB) for all the high- and low-band operating frequencies (a power gain of 30 dB or more may be obtained with two pre-amplification stages, against less than 30 dB with a single pre-amplification stage). Specifically, when the high-band amplification pathway VA_{HB} is activated, the power gain may be reduced, because of the intrinsic gain characteristics of the transistors (for a given output power and therefore transistor size).

The second amplifier DRV2 is connected directly to the intermediate impedance matching network ISMN2, in particular to the capacitor C_{CD} of the common network RCO.

The first amplifier DRV1 and/or the second amplifier DRV2 advantageously comprise a common-gate transistor (T11, T12) and a common-source transistor (T21, T22), in a cascode configuration. This topology makes it possible to maximize the overall gain of the Doherty amplifier.

In the first stage DRV1 and in the second stage DRV2, a MOS transistor (for example, a body-contact MOS (BC-MOS) transistor using SOI technology) may be used for the common-source transistor (T21 and T22), and an LDMOS transistor may be used for the common-gate transistor (T11 and T12). This embodiment is not, however, exclusive, and using the LDMOS transistor for all the transistors of the pre-amplification stage PRA may be envisaged.

It is also possible to envisage other types of transistors or combinations of transistors.

The pre-amplification stage PRA also comprises an input impedance matching network IMN configured to match the input impedance of the first stage DRV1 to a predefined source impedance value (conventionally 50 ohms). For this purpose, a capacitor C10, connected to the input port PE, is connected to the gate of the common source T21 via a capacitor C15. An inductor L11 is connected between an intermediate point, situated between the two capacitors, and ground. The gate of the common source T21 is biased via a resistor R14. The common gate T11 is biased via a resistor R12. A capacitor C13 is connected between the resistor R12 and ground.

Analogously, the pre-amplification stage PRA comprises a second impedance matching network ISMN1 connected between the first stage DRV1 and the second stage DRV2 (inductors L16 and Lₚ₂, resistor R19 and capacitors C17 and C18 connected similarly to the components of the input impedance matching network IMN).

The second impedance matching network ISMN1 may comprise a second-harmonic filter PSH, connected between the gate of the common source T22 and ground. The second-harmonic filter PSH comprises an inductor L_{H2i} in series with a capacitor C_{H2i}, which may be controllable in order to control the second-harmonic impedance with respect to the carrier frequency.

Connecting the first amplifier DRV1 and the second amplifier DRV2 in a cascade may result in instabilities. In order to guarantee stability of the first stage DRV1, a feedback circuit CRE comprising a capacitor C21 and a variable resistor R20 in series is connected between the drain of the common-gate transistor T11 and the gate of the common-source transistor T21.

The value of the variable resistor R20 is controlled in accordance with the amplification pathway selected.

According to one embodiment of the invention, it is also possible to use only a single amplification stage DRV, as FIG. 2c illustrates.

According to one embodiment (using SOI technology), each of the variable capacitors used in the Doherty amplifier is composed of a fixed-value capacitor, of a set of coarse-control capacitors and of a set of fine-control capacitors, connected in parallel. The set of coarse-control capacitors and the set of fine-control capacitors is composed of several branches of variable capacitors, each capacitor being connected to a stack of transistors in order to weight the value of the coarse control or of the fine control.

The quality factor (Q) of the variable capacitor defines the control range TR (ratio between maximum and minimum capacitance value), and the voltage value at the terminals of the capacitor determines the number (N) of stacked transistors as well as the gate width (Wg) of the transistors. Several transistors are stacked in order to withstand the maximum voltage level in the OFF state.

There are other ways of producing the variable capacitors in accordance with the integration technology under consideration (RF-MEMS or BST technologies, for example).

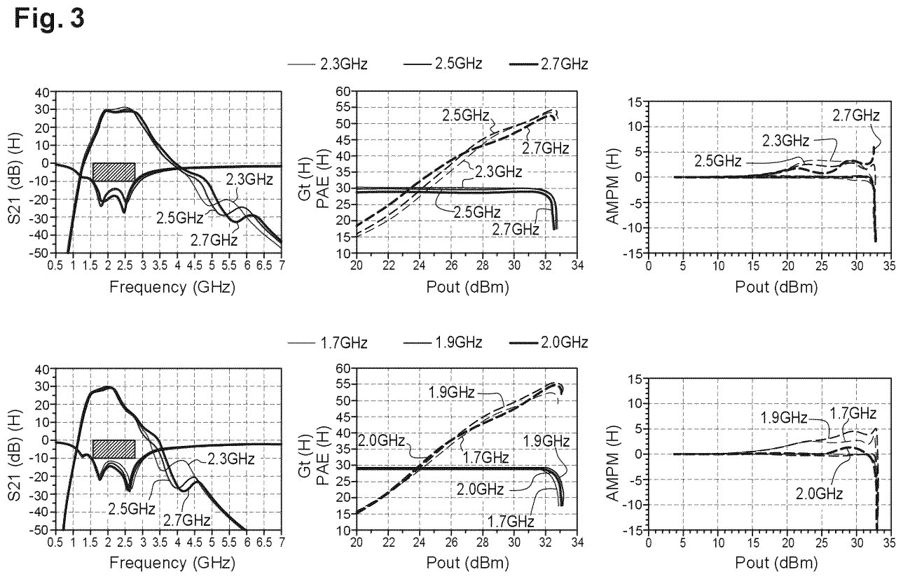

FIG. 3 illustrates the simulated performance of the Doherty amplifier according to the invention, for various operating frequencies. The left-hand column depicts the input-output transmission parameter S21 (power gain, in dB) and input matching parameter S11 as a function of the operating frequency. The middle column depicts the power-added efficiency PAE, in percent, as a function of the output power Pₒᵤₜ (in dBm). The right-hand column depicts the AM/AM (amplitude modulation to amplitude modulation) and AM/PM (amplitude modulation to phase modulation) linearity characteristics.

According to the simulations of the power-added efficiency PAE, the Doherty amplifier makes it possible to maintain high efficiency and, according to the curves of the AM/AM and AM/PM characteristics, very good linearity is obtained over the 1.7-2.7 GHz frequency range.

The performance of the Doherty amplifier according to the invention may also be characterized using a figure of merit FOM defined by the following relationship:

FOM=PAE+|ACLR|

ACLR (for “adjacent channel leakage power ratio”) is defined as the ratio of the filtered average power centred on the attributed channel frequency to the filtered average power centred on an adjacent-channel frequency.

The power-added efficiency PAE makes it possible to correctly characterize energy efficiency, while the filtered average power ratio ACLR makes it possible to correctly characterize linearity in the presence of an amplitude- and phase-modulated transmission signal.

The following table also illustrates the very good performance, in terms of efficiency and in terms of linearity, of the Doherty amplifier according to the invention (ACLR measured for the LTE wireless communication standard, E-UTRA (for “Evolved Universal Terrestrial Radio Access”)).

| Parameter | Low band | | | High band | | | Unit |
|---|---|---|---|---|---|---|---|
| Freq. | 1.7 | 1.8 | 2.0 | 2.3 | 2.5 | 2.7 | GHz |
| Pout | 28 | | | | | | dBm |
| PAE | 40 | 42.1 | 42.8 | 42.8 | 42.7 | 41.2 | % |
| ACLR | −37.7 | −36.6 | −34.8 | −35.7 | −38 | −33.8 | dBc |
| FOM | 77.7 | 78.7 | 77.6 | 78.5 | 80.6 | 75 | |

Thus, the Doherty amplifier makes it possible to obtain a factor of merit FOM greater than 75 over the whole 1.7-2.7 GHz band, providing an output power Pₒᵤₜ equal to 28 dBm, without using digital pre-distortion.

### REFERENCES CITED

[1] RF Power Amplifiers for Wireless Communications, Second Edition, Steve C. Cripps, Artech House, pp. 290-298
[2] P. Draxler and J. Hur, “A multi-band CMOS Doherty PA with tunable matching network”, 2017 IEEE MTT-S International Microwave Symposium (IMS), Honolulu, HI, USA, June 2017, pp. 944-946. doi: 10.1109/MWSYM.2017.8058742
[3] A. Serhan et al., “A Reconfigurable SOI CMOS Doherty Power Amplifier Module for Broadband LTE High-Power User Equipment Applications”, 2020 IEEE Radio Frequency Integrated Circuits Symposium (RFIC), Los Angeles, CA, USA, August 2020, pp. 79-82. doi: 10.1109/RFIC49505.2020.9218305
[4] J. Bachi et al., “A Novel Approach for Doherty PA Design Using a Compact L-C Combiner”, in IEEE Transactions on Circuits and Systems II: Express Briefs, vol. 69, no. 10, pp. 4023-4027, October 2022, doi: 10.1109/TCSII.2022.3185174

1. A Doherty amplifier comprising:
an input port (PE), configured to receive an input RF signal (RF_{IN}) to be amplified; a pre-amplification stage (PRA), configured to amplify the input RF signal (RF_{IN});
at least one output port (PS1, PS2) configured to deliver an amplified RF signal;
further comprising:
a high-band amplification pathway (VA_{HB}), adapted to amplify the input RF signal (RF_{IN}), the operating frequency band of which is located in a frequency band referred to as the upper frequency band;
a low-band amplification pathway (VA_{LB}), adapted to amplify the input RF signal (RF_{IN}), the operating frequency band of which is located in a frequency band referred to as the lower frequency band;
the high-band amplification pathway (VA_{HB}) and the low-band amplification pathway (VA_{LB}) each comprising a main amplifier (AP_{HB}, AP_{LB}), an auxiliary amplifier (AA_{HB}, AA_{LB}), and an output impedance matching network (OMN_{HB}, OMN_{LB}) connected to the main amplifier (AP_{HB}, AP_{LB}), to the auxiliary amplifier (AA_{HB}, AA_{LB}) and to the output port (PS1, PS2);
an intermediate impedance matching network (ISMN2), connected between the pre-amplification stage (PRA) and each of the main amplifiers (AP_{HB}, AP_{LB}) and auxiliary amplifiers (AA_{HB}, AA_{LB}), the intermediate impedance matching network (ISMN2) comprising a common network (RCO) equipped with a switch (SW) configured to selectively activate the high-band amplification pathway (VA_{HB}) or the low-band amplification pathway (VA_{LB}), the switch (SW) comprising an input terminal (BE) connected to the pre-amplification stage (PRA), an output terminal (BS1) connected to the high-band amplification pathway (VA_{HB}), and an output terminal (BS2) connected to the low-band amplification pathway (VA_{LB}).

2. The amplifier according to claim 1, wherein, in both the high-band amplification pathway (VA_{HB}) and the low-band amplification pathway (VA_{LB}), the intermediate impedance matching network (ISMN2) comprises a first tunable resonant network (RRA1_{HB}, RRA1_{LB}) connected to the gate of the main amplifier (AP_{HB}, AP_{LB}) and configured to introduce a predefined first phase shift (ϕₘ), and a second tunable resonant network (RRA2_{HB}, RRA2_{LB}) connected to the gate of the auxiliary amplifier (AA_{HB}, AA_{LB}) and configured to introduce a predefined second phase shift (a), the value of the first phase shift and the value of the second phase shift being determined so that their difference (ϕ_{diff}) has a predefined value in the back-off region of the Doherty amplifier, the second tunable resonant network (RRA2_{HB}) of the high-band amplification pathway (VA_{HB}) comprising an additional inductor (Lₚₐ₁) with respect to the second tunable resonant network (RRA2_{LB}) of the low-band amplification pathway (VA_{LB}).

3. The amplifier according to claim 2, wherein the difference (ϕ_{diff}) is optimized in order to maximize the overall linearity and efficiency of the amplifier.

4. The amplifier according to claim 3, wherein the difference (ϕ_{diff}) is equal to 90°.

5. The amplifier according to claim 2, wherein the first tunable resonant network (RRA1_{HB}, RRA1_{LB}) and the second tunable resonant network (RRA2_{HB}, RRA2_{LB}) comprise variable capacitors.

6. The amplifier according to claim 5, wherein each variable capacitor comprises a fixed-capacitance capacitor, a set of coarse-control capacitors and a set of fine-control capacitors, the set of coarse-control capacitors and the set of fine-control capacitors being composed of several branches of capacitors, each capacitor being connected to a stack of transistors in order to weight the value of the coarse control or of the fine control, respectively.

7. The amplifier according to claim 1, wherein the intermediate impedance matching network (ISMN2) comprises a power divider composed of a first resonant circuit (LC1) arranged in the common network (RCO), of a second resonant circuit (RC2) arranged in the high-band amplification pathway (VA_{HB}), and of a third resonant circuit (RC3) arranged in the low-band amplification pathway (VA_{LB}).

8. The amplifier according to claim 7, wherein the third resonant circuit (RC3) comprises a variable resistor (R_{div2}).

9. The amplifier according to claim 1, wherein the pre-amplification stage (PRA) comprises:
a first stage (DRV1);
an input impedance matching network (IMN) configured to match the input impedance of the first stage (DRV1) to a predefined value;
a second stage (DRV2) connected directly to the intermediate impedance matching network (ISMN2);
a second input impedance matching network (ISMN1) connected between the first stage (DRV1) and the second stage (DRV2).

10. The amplifier according to claim 9, wherein the second input impedance matching network (ISMN1) comprises a second-harmonic filter (PSH).

11. The amplifier according to claim 9, wherein the first stage (DRV1) and/or the second stage (DRV2) comprise a common-gate configuration (T11, T12) and a common-source configuration (T21, T22), in a cascode configuration.

12. The amplifier according to claim 11, wherein a feedback circuit (CRE), comprising a capacitor (C21) and a variable resistor (R20), is connected between the drain of the common-gate transistor (T11) and the gate of the common-source transistor (T21) in the first stage (DRV1), the value of the variable resistor (R20) being controlled in accordance with the amplification pathway activated.

13. The amplifier according to claim 1, wherein the main amplifier (AP_{HB}, AP_{LB}) and the auxiliary amplifier (AA_{HB}, AA_{LB}) of the high-band amplification pathway (VA_{HB}) and of the low-band amplification pathway (VA_{LB}) comprise LDMOS transistors.

14. The amplifier according to claim 1, wherein the output matching network (OMN_{HB}) of the high-band amplification pathway and the output matching network (OMN_{LB}) of the low-band amplification pathway each comprise an output combiner, connected directly to the main amplifier (AP_{HB}, AP_{LB}) and to the auxillary amplifier (AA_{HB}, AA_{LB}).

15. The amplifier according to claim 14, wherein the output combiner comprises an impedance inverter.
